(19) United States
(12) Patent Application Publication
(10) Pub. No.: US 2024/0389258 A1
(43) Pub. Date: Nov. 21, 2024

(54) ELECTRONIC DEVICE COMPRISING PLUG-IN SLOTS FOR ADDITIONAL MODULES

(71) Applicant: Weidmüller Interface GmbH & Co. KG, Detmold (DE)

(72) Inventors: Ralf SCHUMACHER, Lemgo (DE); Ingo GURLT, Bielefeld (DE); Tobias BRANDT, Singapore (SG); Marc STRÜNKMANN, Paderborn (DE)

(21) Appl. No.: 18/688,319

(22) PCT Filed: Oct. 7, 2022
(86) PCT No.: PCT/EP2022/077945

§ 371 Date: Feb. 29, 2024

(30) Foreign Application Priority Data
Oct. 8, 2021 (DE) 10 2021 126 189.9

(51) Int. Cl. H05K 7/14

(52) U.S. Cl. CPC H05K 7/1465; H05K 7/1468

(57) ABSTRACT

An electronic device includes a housing having at least two plug-in receptacles, each intended for one additional module that comprises a module housing. The electronic device is characterised in that the plug-in slots are each arranged in a corner region of the housing so that the relevant module housing of the additional module expands the housing on three outer sides which form a corner. The plug-in slots and the module housings are designed in such a way that each of the module housings fits into each of the plug-in slots.

### BACKGROUND

The invention relates to an electronic device that includes a housing having at least two plug-in receptacles, each intended for an additional module.

In the field of industrial automation technology, it is known to equip housings for electronic devices with plug-in receptacles for additional modules, which expand the functionality of the electronic device or adapt it to particular operating conditions.

The WO 2020/144209 A1 publication, for example, shows an industrial control system unit which provides, in a substantially cuboid housing, plug-in options for additional circuit boards with which radio modules for various radio technologies and/or memory expansion modules can be retrofitted. Housing openings are provided that can be closed with flaps or removable lids to allow access to the radio and/or memory expansions.

The arrangement of the additional modules inside the housing represents a space-saving solution, but includes a disadvantage because an additional module that is removed is unprotected. A further disadvantage is that certain authorizations, e.g. with regard to compatibility with certain radio standards, are only issued for modules that have their own housing, as the housing is one determinant of the properties of the radio modules. In this case, a radio authorization cannot be obtained for the additional module as such, which substantially consists of a circuit board, but only for the entire arrangement of the electronic device with the additional module. This complicates the assurance of radio standards in modular systems.

the EP 2 589 275 B1 publication discloses a functional module, which can be strung together with others, for an input/output system of an industrial automation unit, in which the individual functional modules represent electronic devices into which additional modules in the form of connecting modules can be plugged into plug-in shafts. The connecting modules are available in various connection technologies (e.g. with push-in contacts, with plug-in contacts, etc.), so that the electronic device can be adapted to the conditions of wiring used in the industrial automation unit by selecting a suitable and desired connecting module.

Such additional modules are plugged into the push-in shafts and have an entire housing except for a plug-in arrangement situated at the front in the push-in direction. Accordingly, a removed additional module is well protected and could also receive its own radio authorization. However, the arrangement of an entire housing inside an entire housing is not particularly space-saving and is also problematic with regard to good thermal dissipation of heat generated in the additional module.

The CN 206461641 U publication shows a network gateway having a housing with a plug-in receptacle for an additional module via which a wireless connection can be established. A required radio protocol for the wireless connection can be selected by exchanging the additional module. The plug-in receptacle is arranged in an edge area of the housing, with two side surfaces of the additional module completing the housing of the gateway.

### SUMMARY OF THE INVENTION

It is an object of the present disclosure to provide an electronic device with at least two additional modules, in which the additional modules are protected when in the removed state and nevertheless can be employed flexibly in the electronic device with little additional space required.

The electronic device includes plug-in receptacles that are each arranged in a corner region of the housing so that the relevant module housing of the additional module expands the housing on three outer sides respectively which form a corner, wherein the plug-in receptacles and the module housings are designed in such a way that each of the module housings fits into each of the plug-in receptacles.

In other words, three sides of the module housing form parts of the outer side surfaces of the electronic device. Advantageously, the additional module thus has its own housing—the module housing—so that it qualifies as an independent electronic device and can, for example, obtain an independent radio device approval if the additional module is a radio module for expanding the radio connectivity of the electronic device. At the same time, even when the additional module is in the inserted state, double housing walls, which would take up space and which in certain circumstances could impair radio broadcasting, are not formed at the three sides depicted. Thus, use can be made of the advantages of the independent module housing without this module housing leading to an excessively large additional volume consumption of the usable internal volume of the electronic device.

Due to the plug-in receptacles and the module housings being configured in such a way that each of the module housings fits into each of the plug-in receptacles, the module housings can be employed flexibly on the electronic device.

In one embodiment of the electronic device, guides provide on the housing linearly guide the additional module in the corner. This facilitates pushing-in and ensures that plug-in connectors of the additional module are well positioned and plugged in at a correct angle.

In a further embodiment of the electronic device, at least three housing sides that are adjacent one another in a corner are configured in the module housing, specifically a longitudinal side, at least one transverse side and a front side. Due to three different sides of the module housing being accessible even after insertion into the electronic device, there is a great deal of flexibility in the arrangement of connection, operating and/or signalling elements. For example, connection, operating and/or signalling elements can be arranged on the front side. In particular in the case of electrical devices that are arranged and strung together on mounting rails in switch cabinets, the longitudinal side is not accessible, and the transverse side is only accessible to a limited extent when installed.

Furthermore, two transverse sides oriented parallel to one another can be configured in the module housing, whereby the additional module can optionally be used on the two different corners if these are arranged on one side of the housing. Furthermore, the module housing can have a rear side arranged parallel to the longitudinal side, which is preferably only partially formed, thus ensuring good air circulation within the housing to the installation space of the additional module.

In another embodiment of the electronic device, the module housing and the housing have a locking mechanism to fix the additional module in the plug-in receptacle. The locking mechanism can, for example, have a locking tab and a latching lug that engages the locking tab. A lever which releases the locking mechanism when in a pivoted-up position is preferably mounted on the module housing. The lever may therefore be used to unlock and to aid removal. For this purpose, the locking tab can be resiliently arranged on the module housing and is pushed back depending on the pivoting position of the lever to release the locking mechanism. Also, the lever can be pivoted down on both sides and lock the module housing in the plug-in receptacle in both pivoted-down positions, as a result of which the module is able to be used at different corner regions.

In yet a further embodiment of the electronic device, there is arranged in the housing a main circuit board, on which at least one plug-in base is located. The additional module is plugged into the plug-in base with a plug-in connector. The at least one plug-in base is preferably arranged in a part of the main circuit board that is angled by a flexible section. This type of tethering of the plug-in base to the main circuit board is electrically advantageous and simple to implement, in mechanical terms, and to mount. The arrangement of the plug-in base, which is angled relative to the main orientation of the main circuit board, facilitates a plug-in or push-in direction of the additional modules parallel to the main orientation of the main circuit board.

In yet another embodiment, the electronic device has a connecting module which is pushed into a push-in shaft of the housing and which contacts the main circuit board, e.g. via a circuit board edge connector. On or in the housing, an ejection lever is preferably pivotably mounted, which has a first lever arm that protrudes from the housing and a second lever arm that adjoins a lower side of the connecting module. With the aid of the ejection lever, the connecting module can be ejected and, if necessary, initially unlocked. In particular, if the connecting module is positioned directly adjacent to the additional module, only the ejection lever facilitates or enables removal of the connecting module.

The electronic device can be a radio network device, for example an IoT (Internet of Things) gateway, with the at least one additional module being a radio module. Through the modularity provided by the additional module, the electronic device can be adapted for the use of different, including future, radio standards.

### BRIEF DESCRIPTION OF THE DRAWINGS

The invention will be explained in greater detail below using an exemplary embodiment with the aid of figures. In the figures:

FIG. 1 is an isometric view of an electronic device with the additional module removed according to the present disclosure;

FIG. 2 is an isometric view of the electronic device according to FIG. 1 with an inserted additional module;

FIG. 3 is an isometric view of the electronic device as in FIG. 1 with an inserted and locked additional module;

FIGS. 4 and 5 are isometric views of the electronic device according to FIG. 3 with an inserted and locked additional module;

FIG. 6 is a plan view of the electronic device of FIGS. 4 and 5;

FIGS. 7a and 7b are isometric views of a separate additional module in different locking positions;

FIG. 7c is a partial view of a locking mechanism of the additional module of FIGS. 7a and 7b;

FIG. 8 is a top isometric view of the inner structure of the electronic device without an additional module and with the housing only partially depicted;

FIGS. 9 and 10 are isometric views of the electronic device according to FIG. 2 with the connecting module partially and entirely removed, respectively; and

FIG. 11 is a partial view of an ejection mechanism for the connection module.

### DETAILED DESCRIPTION

The figures as described herein show an exemplary embodiment of an electronic device. Identical reference numbers in all figures denote identical or identically acting elements. For the sake of clarity, not every element is provided with a reference number in each figure.

An IoT (Internet of Things) gateway is depicted by way of example as an electronic device in the figures. Of course, the concepts described within the framework of this application can also be transferred to other electronic devices, e.g. to an industrial control system or to an expansion module for industrial control systems which provides an additional mobile communications network connection such as LTE, 4G or 5G.

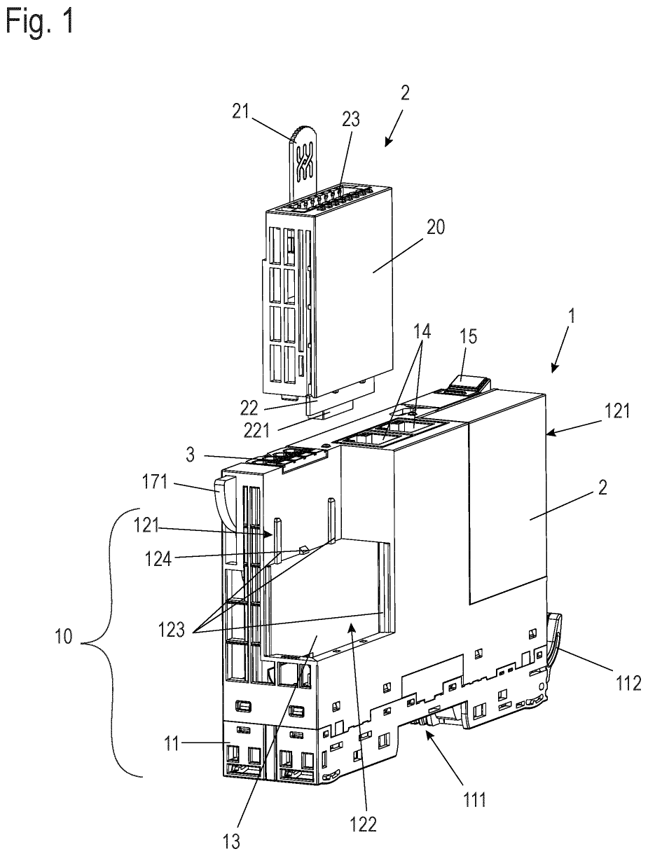

FIG. 1 shows the electronic device in an isometric depiction. It comprises a basic device 1, which provides two plug-in options for additional modules 2. One of the additional modules 2 is already plugged into the basic device 1. The other additional module 2 is depicted separately from the basic device 1, for example in a situation shortly before the additional module 2 is plugged into the basic device 1. Furthermore, a connection module 3 is inserted into the basic device 1.

The basic device 1 is designed as a device that can be used in a switch cabinet, for example, to be placed onto a mounting rail such as a top-hat rail. It has a housing 10 composed of a base 11 and a cover 12. A mounting rail receptacle 111 is configured in the base 11, with which the electronic device can be placed onto the mounting rail. The electronic device 1 latches onto the mounting rail. A locking mechanism is provided, which can be released with the aid of a release lever 112 in order to remove the electronic device from the mounting rail again.

The cover 12 is placed on the base 11, in particular latched to the base 11. A main circuit board 13 is accommodated inside the housing 10. In alternative configurations of the electronic device, the width of the housing 10 (the width is the extension in the direction of the mounting rail) can be larger, so that several comparable main circuit boards 13 or one main circuit board 13 and one or more additional circuit boards can also be arranged in the housing 10.

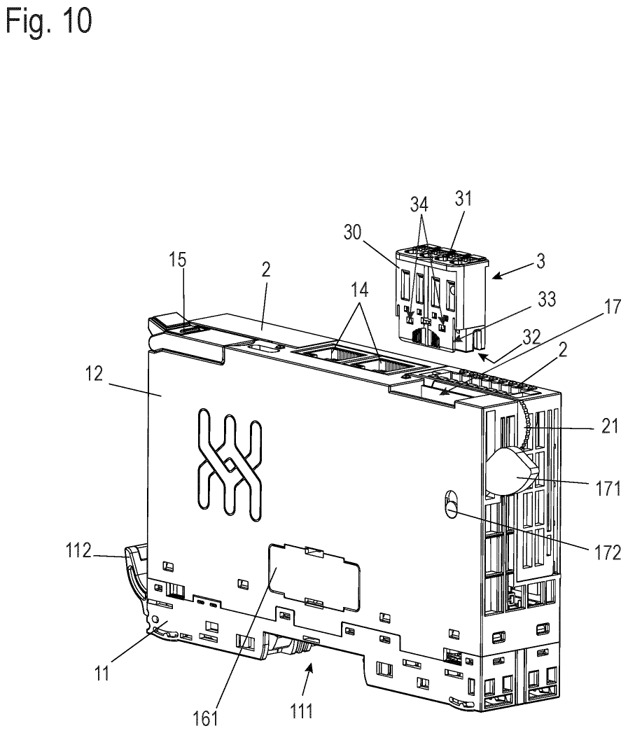

Connection elements 14 are arranged on the side of the cover 12 opposite the base 11, i.e. on the side pointing upward in FIG. 1, which faces the user when installed in a switch cabinet. By way of example, two RJ-45 network connections can be seen in the depicted electronic device. Operating and/or signalling elements may also be present. Furthermore, a push-in shaft 17 (shown in FIG. 10 is configured in this area. The connecting module 3 is thus accessible on its upper side, on which connections 31 are located. Power supply connections and/or signal connections for the electronic device can be arranged here, which in this case are in the form of push-in conductor connections.

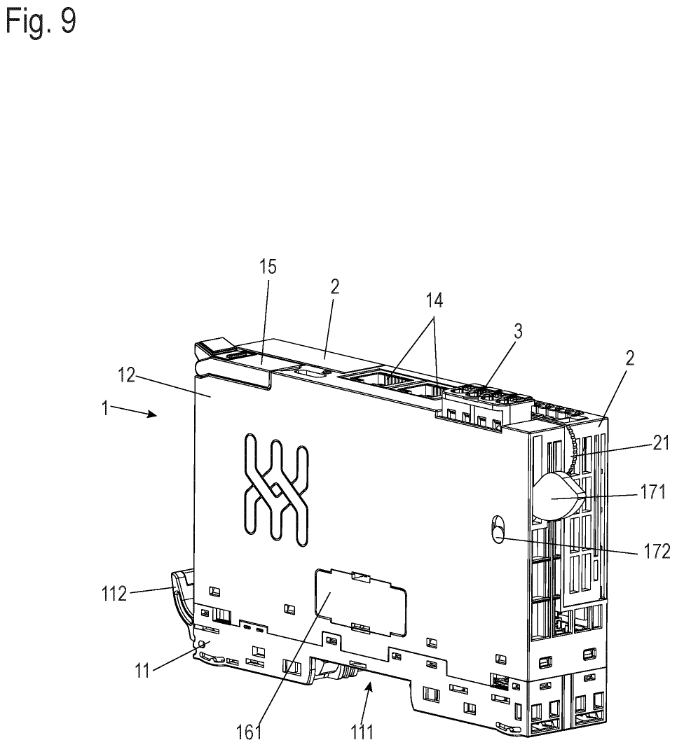

To the aforementioned push-in shaft 17 for the connecting module 3, there is assigned an ejection lever 171, which, when actuated, pushes the otherwise inaccessible or only poorly accessible connecting module 3 out of the push-in shaft 17 so that it can be removed. This is depicted once again in greater detail in FIGS. 9 to 11.

Moreover, a cover flap 15 which can be pivoted up and under which additional elements are located, is arranged on the upper side of the cover 12. These may be elements that do not have to be used regularly, e.g. a button for resetting the electronic device or a service connection. It may also be envisaged to arrange access to a battery compartment for a backup battery or a plug-in option for a memory card under the cover flap 15.

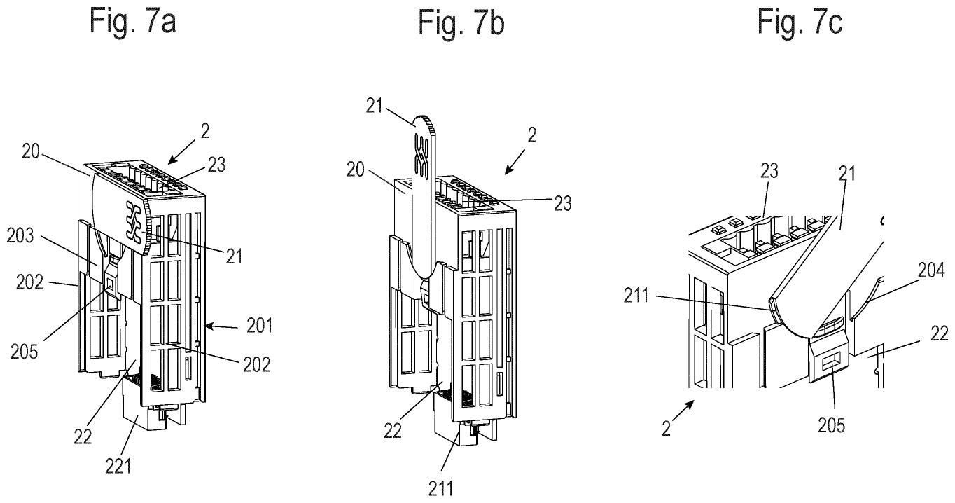

The additional module 2 likewise has a housing which is referred to hereafter as a module housing 20, to differentiate it from the housing 10 of the basic device 1. On the module housing 20, there is arranged a pivotable lever 21 which on the one hand serves to lock the additional module 2 onto the housing 10 and on the other hand functions as a gripping tab. The structure of the additional module 2, and in particular the arrangement of the lever 21 on the housing 20, will be described further in greater detail below in connection with FIGS. 7a-c.

At a lower end of the additional module 2 opposite the lever 21, there is a module circuit board 22, which, in the depicted examplary embodiment, protrudes slightly downwards beyond the module housing 20. A plug-in connector 221 is arranged on the module circuit board 22, via which contact is made between the additional module 2 and the main circuit board 13 of the basic device 1 when the additional module 2 is in the plugged-in state. Finally, on the not yet inserted additional module 2, there are arranged connection, operating and/or signalling elements 23 which can vary depending on the functionality of the additional module 2, or, as in the case of the already inserted additional module 2, can be dispensed with if they are not required. The latter is also the case with an additional module 2 which is inserted into the basic device 1 as a kind of dummy module, but which does not offer any additional electronic functionality.

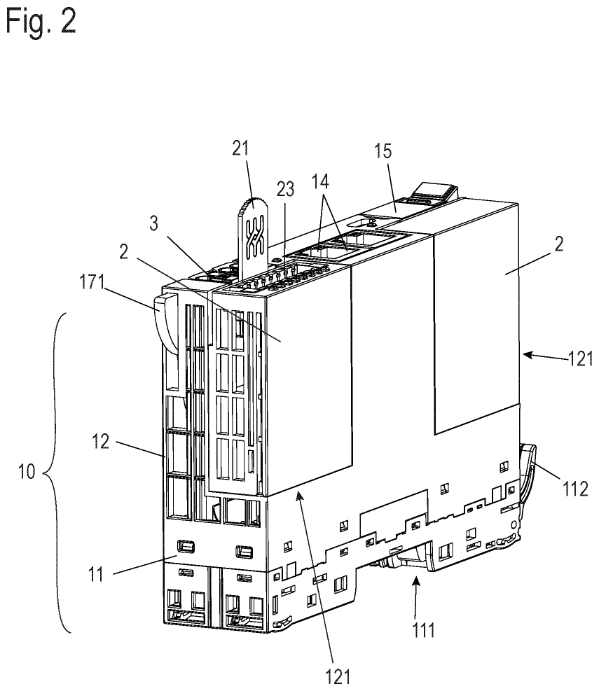

FIG. 2 shows the electronic device from FIG. 1 from the same perspective but after insertion of the additional module 2 into the plug-in area on the basic device 1. This area is a corner region 121 of the housing 10 of the basic device 1, wherein the module housing 20 supplements the housing 10 by the otherwise missing corner to form a cuboid shape. Thus, in the inserted state of the additional module 2, three sides of the module housing 20 form outer surfaces of the electronic device.

Advantageously, the additional module 2 has its own housing—the module housing 20—so that it qualifies as an independent electronic device and can, for example, obtain an independent radio device approval if the additional module 2 is a radio module for expanding the radio connectivity of the electronic device. At the same time, even when the additional module 2 is in the inserted state, double housing walls that would take up space are not formed at the three depicted sides. Thus, use can be made of the advantages of the independent module housing 20 without this module housing 20 leading to an excessively large additional volume consumption of the usable internal volume of the electronic device 2.

As can be seen in FIG. 1, there is nevertheless a large opening 122 in the cover 12 in the receiving area of the additional module 2, via which air can circulate between the installation space within the cover 12 and the installation space within the additional module 2, for example for convection cooling of the electronic device in the additional module 2. Due to perforated side walls, convection is also possible directly between the additional module 2 and the surrounding environment.

In the depicted exemplary embodiment, the additional modules 2 are connected perpendicular to the mounting rail, which is also possible if the electronic device is directly adjacent to a neighbouring device on the mounting rail. Guides 123 are formed on the cover 12, which linearly guide the pushing-in of the additional module 2 in the corner region 121. The guides 123 may be ridges, undercut ridges, e.g. with a dovetail cross-sectional profile.

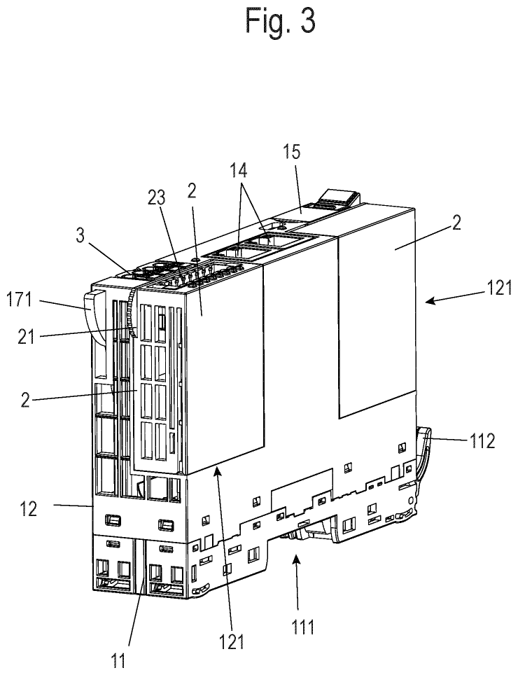

FIG. 3 shows the additional module 2 in the inserted and locked state. Locking is achieved by pivoting the lever 21 toward the outer side. Details of the locking mechanism are explained with reference to FIGS. 7a-c. First, it should be noted that the additional module 2 can be inserted into the basic device 1 in an unchanged design at both depicted plug-in options for the additional modules 2. For this purpose, the lever 21 can be pivoted to each of the two sides, whereby unlocking takes place in the center position (see FIGS. 1 and 2) and locking takes place in each of the tilted-back side positions.

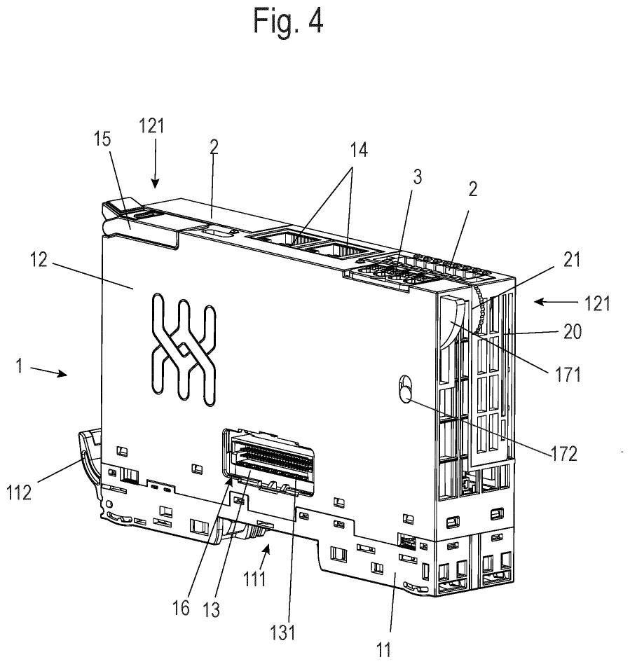

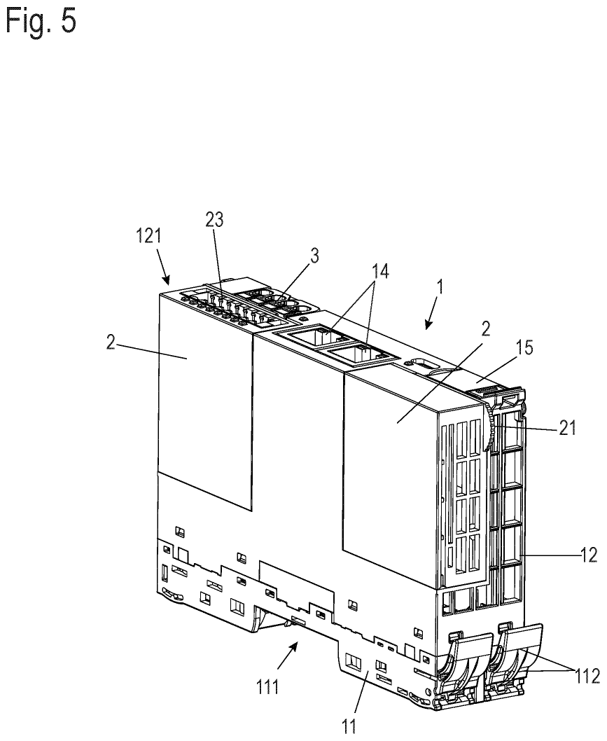

FIGS. 4 and 5 show the electronic device once again from different perspectives. The side of the housing 10 opposite the additional modules 2 can be seen in FIG. 4. FIG. 5, like FIG. 3, shows the side of the housing 10 in which the additional modules are 2 arranged, but showing the opposite face side of the housing 10.

FIG. 4 shows an access opening 16, behind which an expansion plug is located on the main circuit board 13. The electronic device can be coupled to a further device, for example an expansion module, via the expansion plug which is arranged on the top-hat or mounting rail alongside the electronic device. If not required, the access opening 16 can be closed by a lid, which is not shown here.

FIG. 4 also shows a pivot bearing 172 of the ejection lever 171. The ejection lever 171 is pivotably mounted on the side wall of the cover 12, wherein a bearing opening is arranged in the form of a keyhole which is undercut in the lower region. A protruding bearing pin is also arranged on the ejection lever 171 with an undercut. The bearing pin can be inserted into the bearing opening 172 in the upper area and can be displaced downward into the bearing position. In this position, the ejection lever 171 is pivotably borne on the side wall of the cover 12 without any components of the bearing protruding beyond the outer surface of the cover 12. It should be noted that the bearing of the lever 21 on the module housing 20 can be designed in a comparable manner.

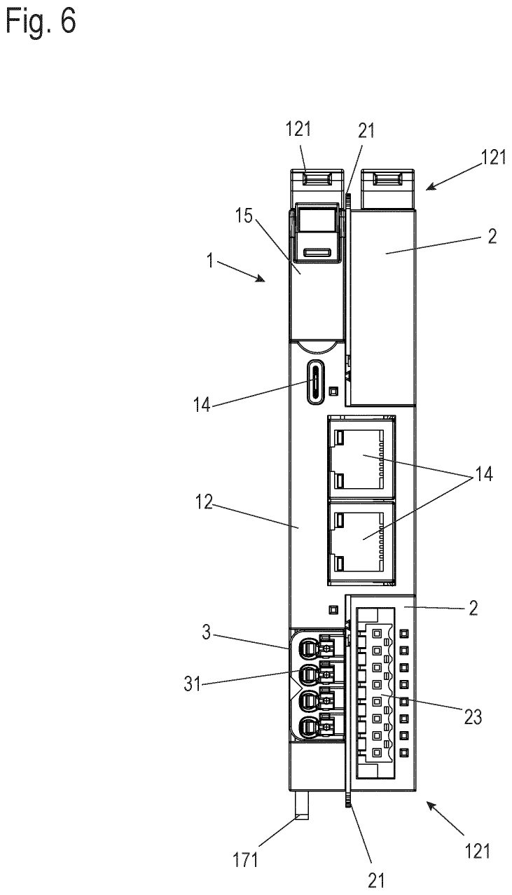

Referring now to FIG. 6, there is shown the upper side of the electronic device. In addition to the RJ45 sockets already discussed, a USB-C socket is provided as a further connection element 14. There are also contacts 31, in this case push-in contacts, of the connecting module 3.

FIGS. 7a and 7b show the additional module 2 in a more detailed manner. The viewing direction here is at an angle to a transverse side 202 of the module housing 20 and a rear side 203. The rear side 203 is the side with which the additional module 2 is arranged in the basic device 1, parallel to the main circuit board 13 and facing it. A longitudinal side 201, which is not visible here but rather indicated via a reference arrow, is formed parallel to the rear side 203 and also between the transverse sides 202. This longitudinal side 201 is closed, as is shown in FIG. 5.

In contrast, the transverse sides 202 are perforated, which enables the aforementioned exchange of air with the surrounding environment. FIGS. 7a and 7b also show that the transverse side 202 is formed on each of the sides of the additional module 2, as a result of which the additional module 2 can be used in both insertion positions in the basic device 1. Sometimes one and sometimes the other of the transverse sides 202 completes the housing of the electronic device.

In the lower region of the rear side 203, there is configured a resilient tab 205 which interacts with a latching lug 124 on the module housing 10 to fix the module housing 20 in the housing 10.

FIG. 7a shows the locked state of the module housing 20. In this state, the resilient tab 205 assumes a latching position which corresponds to its normal spring preloading position. If the lever 21 is brought into the unlocking position, as depicted in in FIG. 7b, a lower end of the lever 21 pushes the resilient tab 205 in the direction of the interior of the module housing 20. As a result, the lock connection between the latching lug 124 and the housing 10 is undone and the module housing 20 can be removed. In order to be able to exert the necessary pressure forces on the latching tab 205 in the lower region of the lever 21, the lower end of the lever 21 is provided with a groove 211, as shown in FIG. 7c. This groove 211 engages a guiding ridge 204, which is formed laterally next to the latching tab 205 on the rear side 203. The guiding ridge 204 is interrupted in the region of the latching tab 205, but in such a way that a section of the guiding ridge 204 engages the groove 211 at every pivot angle of the lever 21.

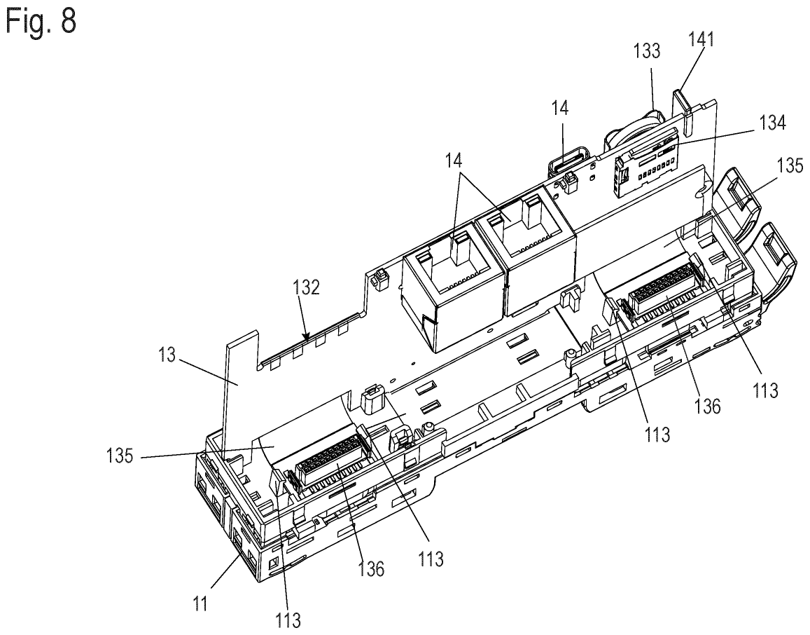

FIG. 8 shows the basic device 1 of the electronic device, with the cover 12 of the housing 10 having been removed in order to obtain an insight into the inner structure of the basic device 1.

In particular, the main circuit board 13, which is oriented substantially perpendicular to the top-hat or mounting rail, is shown. The aforementioned connection elements 14, in this case the two RJ45 sockets and the USB-C socket, are on an upper edge of the circuit board. Furthermore, signaling elements 141, in this case light-conducting elements, are assigned to individual signal LEDs arranged on the circuit board 13. There are also elements concealed under the cover flap 15, specifically a battery compartment 133 for accommodating a button cell as a backup battery and a memory card slot 134, which in the present case is designed to accommodate an SD card.

Along an upper circuit board edge of the circuit board 13, in a lowered step, there are also provided circuit board edge contacts 132, which make contact with the plugged-in connecting module 3. This connecting module has a corresponding circuit board edge connector for this purpose.

Plug-in bases 136 are arranged on the circuit board to connect the circuit board 13 and the electronic components arranged on it to the additional module 2. Plug-in connectors 221 of the additional modules are plugged into the plug-in bases, which are arranged on tongue-like extensions on the circuit board 13, which have flexible sections 135 as a whole or in a transition area. By means of the flexible sections 135, the circuit board 13, which otherwise stands perpendicularly in the base 11, can be bent and is oriented parallel to a base plate of the base 11 in the area of the plug-in base 136. In order to keep this section in the depicted state, it is overlapped by latching hooks 113, which are arranged on the base 11 or are integral with the base 11.

This type of tethering of the plug-in base 136 to the main circuit board 13 is electrically advantageous and simple to implement, in mechanical terms, and to mount. The plug-in base 136 is arranged at an angle relative to the main orientation of the main circuit board 13, which facilitates a plug-in or push-in direction of the additional modules 2 parallel to the main orientation of the main circuit board 13. Thus, the additional modules 2 are ultimately pushed in perpendicular to the mounting rail, which is also possible if the electronic device is directly adjacent to a neighbouring device on the mounting rail.

Once again, in a similar way to FIG. 4, the electronic device is shown in FIGS. 9 and 10, with a view onto the side opposite the additional modules 2. In contrast to in FIG. 4, the access opening 16 shown there is closed here with a cover 161.

FIGS. 9 and 10 illustrate the removal of the connecting module 3. This is performed via pressure on the ejection lever 171, as a result of which the module 3 is pushed so far out of the push-in shaft 17 (shown in FIG. 9) that it can be gripped and fully removed, as is depicted in FIG. 10. The push-in shaft 17, into which the connecting module 3 is inserted, is shown in FIG. 10. Furthermore, in the removed connecting module 3, a circuit board edge connector 32, with which the connecting module 3 contacts the circuit board edge contacts 132 (shown in FIG. 8) of the main circuit board 13, is shown in a rudimentary manner in the lower area opposite the connection contacts 31.

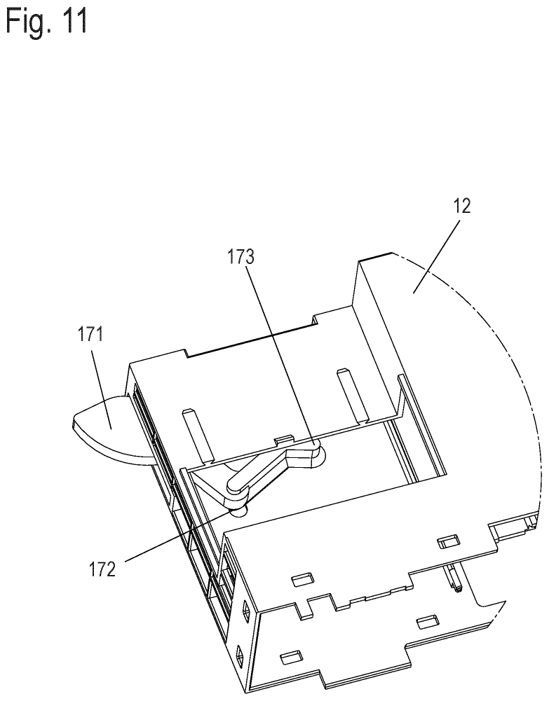

Finally, FIG. 11 shows a cutout of the cover 12 of the housing 10 of the basic device 1 in the area of the push-in shaft 17. The shape of the ejection lever 171 can be seen here. The ejection lever 171 is a two-sided lever, wherein a bevelled lever section 173 arranged in the interior is lifted via pressure on the externally accessible and visible part to lift the inserted connecting module 3. When the ejection lever 171 is actuated, the bevelled lever section 173 moves a latching tab 33 with latching elements 34 of the connecting module 3 away from the wall of the cover 12, thereby undoing a latch connection of the connecting module 3 in the push-in shaft 17. The ejection lever 171 thus assumes a dual function by releasing the latch connection of the connecting module 3 and lifting the connecting module 3.

FIG. 11 shows the ejection lever 171 during its installation. It is inserted by its undercut bearing pin 172 into the upper part of the keyhole-shaped opening in the cover 12. In the operating position, it is pushed into the lower part of this keyhole opening in which it is then fixed.

1-21. (canceled)

22. An electronic device comprising a housing having at least two plug-in receptacles, each plug-in receptacle intended for an additional module having a module housing wherein the plug-in receptacles are each arranged in a corner region of the device housing so that when the relevant module housing of each additional module is connected with the housing it expands the device housing on three outer sides to form a corner, the plug-in slots and the module housings being designed such that each module housing fits into a plug-in slot.

23. The electronic device according to claim 1, wherein guides are provided on the housing to linearly guide the additional module in the corner region, are provided on the housing.

24. The electronic device according to claim 1, wherein the module housing includes at least a longitudinal side, at least one transverse side and a front side that are adjacent one another in a corner of the module housing.

25. The electronic device according to claim 3, wherein at least one of connection, operating and signaling elements are arranged on the module front side.

26. The electronic device according to claim 3, wherein the module housing includes two transverse sides oriented parallel to one another.

27. The electronic device according to claim 3, wherein the module housing has a rear side arranged parallel to the longitudinal side.

28. The electronic device according to claim 6, wherein the rear side is partly formed.

29. The electronic device according to claim 1, wherein the module housing and the device housing have a locking mechanism to fix the additional module in the plug-in receptacle.

30. The electronic device according to claim 8, wherein the locking mechanism has a locking tab and a latching tab which engages the locking tab.

31. The electronic device according to claim 9, wherein a lever is pivotably mounted on the module housing to release the locking mechanism when in a pivoted-up position.

32. The electronic device according to claim 10, wherein the lever is downwardly pivotable on both sides to lock the module housing in the plug-in receptacle.

33. The electronic device according to claim 9, wherein the locking tab is resiliently arranged on the module housing and is pushed back depending on the position of the lever to release the locking mechanism.

34. The electronic device according to claim 1, wherein the device housing has a main circuit board, the main circuit board having at least one plug-in base arranged thereon and into which the additional module is plugged.

35. The electronic device according to claim 13, wherein the at least one plug-in base is arranged in a part of the main circuit board angled by a flexible section.

36. The electronic device according to claim 13, wherein a plug-in direction of the additional module runs parallel to the main circuit board.

37. The electronic device according to claim 1, and further comprising a connecting module inserted into a push-in shaft of the device housing.

38. The electronic device according to claim 16, wherein the connecting module has a circuit board edge connector.

39. The electronic device according to claim 16, wherein the device housing includes a pivotably mounted ejection lever having a first lever arm that protrudes from the device housing and a second lever arm that adjoins a lower side of the connecting module.

40. The electronic device according to claim 1, wherein the two device housing corner regions are arranged adjacent to the at least two plug-in receptacles for the additional modules.

41. The electronic device according to claim 1, and further comprising a mounting rail receptacle for placing the electronic device onto a mounting rail.

42. The electronic device according to claim 1, configured as an Internet of Things gateway, wherein the at least one additional module is a radio module.
